(19) United States
(12) Patent Application Publication
(10) Pub. No.: US 2025/0374494 A1
(43) Pub. Date: Dec. 4, 2025

(54) ELECTROMAGNETIC SHIELDING CAP FOR ELECTRONIC CIRCUITS

(71) Applicant: STMicroelectronics International N.V., Geneva (CH)

(72) Inventors: Nicolas MASTROMAURO, Lumbin (FR); Karine SAXOD, Porte de Savoie (FR)

(73) Assignee: STMicroelectronics International N.V., Geneva (CH)

(21) Appl. No.: 19/214,674

(22) Filed: May 21, 2025

(30) Foreign Application Priority Data
May 30, 2024 (FR) FR2405583

(51) Int. Cl. H05K 9/00

(52) U.S. Cl. CPC H05K 9/0028

(57) ABSTRACT

An electromagnetic shielding cap for an electronic circuit includes a main surface and four lateral surfaces. One of the lateral surfaces has, at its base, soldering zones. Each soldering zone is delimited by openings. An electronic circuit, particularly an optical transmission and/or reception circuit, includes a chip bonded to a first main surface of a substrate locally covered by metal pads. The electromagnetic shielding cap is mounted over the circuit. The cap and the substrate are assembled to each other by solder joints, where each solder joint is soldered to one of the metal pads and to one of the soldering zones.

### PRIORITY CLAIM

This application claims the priority benefit of French Application for Patent No. FR2405583, filed on May 30, 2024, the content of which is hereby incorporated by reference in its entirety to the maximum extent allowable by law.

### TECHNICAL FIELD

The present disclosure generally concerns the field of electronic circuits and, in particular, electromagnetic shielding caps intended to protect electronic circuits, especially those including light radiation emitters and/or light radiation receivers.

### BACKGROUND

Some electronic circuits comprise an electronic chip housed in a package. The package typically comprises a support portion having the chip bonded thereto, and a cover portion covering the chip. The cover is mounted on the support portion. It is, for example, made of resin.

When electronic chips comprise optical signal transmission and reception regions, the cover portions comprises, opposite the transmission/reception regions, elements transparent to the wavelengths of the optical signals and an inner wall, delimiting two cavities, one for the transmission region and one for the reception region.

Such electronic circuits are used, for example, to form time-of-flight (TOF) proximity sensors to detect the presence or the absence of an object located in front of the package cover.

Since such electronic circuits are sensitive to electromagnetic waves, an electromagnetic shielding has to be added. For this purpose, a metal cap may be positioned on the cover. It may be bonded to the support substrate via a bead of glue.

However, due to the bead calibration difficulties, there appear a number of disadvantages. There exists a risk for the bonding material to flow by capillarity, inside the cap, which might hinder the proper operation of the electronic component. Further, the strength of the cap bonding is uncertain.

There exists a need to provide an electromagnetic shielding cap for an electronic circuit capable of being easily assembled to an electronic circuit in order to protect it from electromagnetic waves, and a method of assembling an electronic circuit implementing such a cap, the obtained cap having to exhibit a good mechanical strength.

### SUMMARY

In an embodiment, an electromagnetic shielding cap for an electronic circuit comprises a main surface and four lateral surfaces, a first lateral surface having, at its base, soldering zones, each soldering zone being delimited by a plurality of openings.

According to a specific embodiment, each soldering zone is delimited by three openings formed by a top opening and two lateral openings, the lateral openings being perpendicular to the top opening and perpendicular to the base of the first lateral surface.

According to a specific embodiment, the first lateral surface has a height smaller than the height of the other lateral surfaces.

According to a specific embodiment, the cap is made of metal, preferably of stainless steel or of copper.

In an embodiment, a method of manufacturing an electromagnetic shielding cap for an electronic circuit, such as previously defined, comprises forming the openings in the cap by punching.

In an embodiment, an electronic circuit, in particular an optical transmission and/or reception circuit, comprises a chip attached to a first main surface of a substrate and an electromagnetic shielding cap such as previously defined, the first main surface of the substrate being locally covered by metal pads, the cap and the substrate being assembled to each other by means of solder joints, each solder joint being soldered both to one of the metal pads of the substrate and to one of the soldering zones of the cap.

According to a specific embodiment, at least one of the other lateral surfaces of the cap covers one of the flanks of the substrate, preferably in which the other three lateral surfaces each cover one of the flanks of the substrate.

According to a specific embodiment, an additional cap made of a polymer material is positioned on the first surface of the substrate and is covered by the electromagnetic shielding cap, the additional cap defining a cavity having the chip positioned therein, the electromagnetic shielding cap being capable being bonded to the additional cap by means of a glue layer.

According to a specific embodiment, the surface area ratio between a soldering zone and a metal pad, soldered to each other, is approximately 1.

According to a specific embodiment, the cap covers at least 80%, preferably at least 90%, of the surface area of the first main surface of the substrate.

In an embodiment, a method of manufacturing an electronic circuit such as previously defined, comprises: positioning an electromagnetic shielding cap for an electronic circuit, such as previously defined, on a first main surface of a substrate, a chip being arranged on the first main surface of the substrate, a periphery of the first main surface of the substrate being locally covered by metal pads, the cap being positioned so that the soldering zones are arranged at the level of the metal pads of the substrate; and soldering to form solder joints, each solder joint being soldered both to one of the metal pads of the substrate and to one of the soldering zones of the cap.

According to a specific embodiment, the solder step is carried out by solder ball jetting.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, in exploded view, an electronic circuit;

FIG. 2 shows, in three dimensions, a portion of an electronic circuit;

FIG. 3 shows, in front view, a portion of an electronic; and

FIG. 4A and FIG. 4B show, schematically and in front view, the solder joints of an electronic circuit.

### DETAILED DESCRIPTION

The various elements are not necessarily all to the same scale, to make the drawings more readable.

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

By between X and Y, there is meant that limits X and Y are included in the range of values.

By radio frequency wave, there is meant an electromagnetic wave having a frequency between 3 kHz and 3,000 GHz, more particularly between 3 kHz and 6 GHz, and more particularly still 100 kHz and 6 GHz.

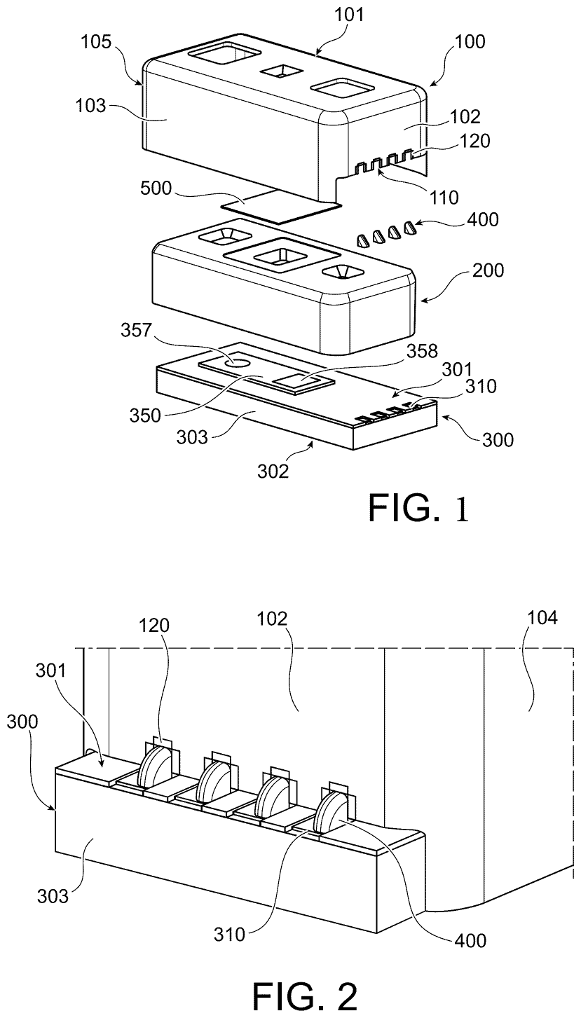

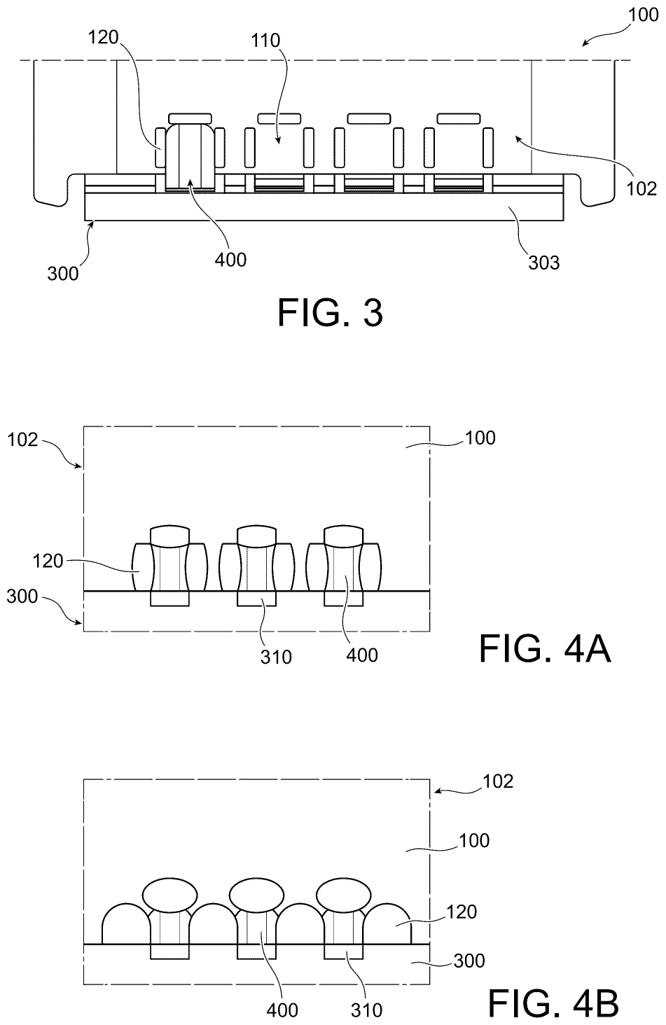

The various elements of the electronic circuit will be described in detail, referring to FIG. 1, to FIG. 2, and to FIG. 3.

The electronic circuit comprises a support substrate 300 on which an electronic chip 350 is positioned, a first cap called outer cap 100, and a second cap called inner cap 200. Outer cap 100 covers inner cap 200. Outer cap 100 plays the role of an electromagnetic shield, particularly against radio frequencies.

Support substrate 300 (also called substrate or support) comprises a first main surface 301 (front surface), a second main surface 302 (rear surface) substantially parallel to the first main surface, and flanks 303. Flanks 303 extend from the first main surface 301 to the second main surface 302. The contour of the support substrate is, for example, square or rectangular.

A portion of the periphery of the first surface 301 of support substrate 300 is covered by metal pads 310 intended for the assembly with outer cap 100. Metal pads 310 may be arranged on two sides of the first surface 301 to bond cover 100 to two sides of substrate 300. Metal pads 310 are preferably arranged on one and the same side of the first surface 301.

Metal pads 310 are made of a metal or of a metal alloy. Metal pads 310 are, for example, made of copper.

Support substrate 300 is made of a dielectric material. It comprises electrical connections (not shown) running from the first main surface 301 to the second main surface 302.

Substrate 300 is an interconnection substrate enabling to couple the electronic circuit to an external device or to a substrate of printed circuit board (PCB) type.

The rear surface 302 of support substrate 300 may be provided with electrical metal pads to connect the electronic package to an external element.

Electronic integrated circuit (IC) chip 350 (more simply called chip) 350 is arranged on substrate 300 and more particularly on the first main surface 301 of support substrate 300. It is, for example, arranged on a central portion of support 300.

Chip 350 is electrically coupled to the electrical connection network of support substrate 300 via an element ensuring the electrical connection, such as wires or balls. A glue layer (not shown) may be interposed between the front surface 301 of support substrate 300 and a rear surface of electronic chip 350.

According to an embodiment, chip 350 comprises an optical transmission (light-emitting) portion 357 and an optical reception (light-receiving) portion 358.

Light-emitting portion 357 is configured to transmit a light signal and light-receiving portion 358 is configured to detect an incident light signal. Light-emitting portion 357 and light-receiving portion 358 are intended to cooperate in such a way as to measure a distance by time of flight of the light signal transmitted and then incident after a reflection.

Alternatively, two chips could be used, one being a light-emitting chip configured to transmit a light signal and the other being a light-receiving chip configured to detect an incident light signal.

The electronic circuit comprises an inner cap 200 located above and at a distance from chip 350, parallel to support substrate 300. Inner cap 200 comprises a main surface (also referred to as a front surface or upper surface) and lateral surfaces. The chip is housed in inner cap 200.

Inner cap 200 has a contour lower than that of support substrate 300. The feet of the lateral surfaces are mechanically assembled to the first surface 301 of substrate 300. The assembly may be performed by means of an adhesive or of a glue.

Inner cap 200 comprises one or a plurality of inner walls in the form of plates. The walls are opaque.

The inner wall(s) separate the optical transmission/reception regions 357, 358 from chip 350.

Inner cap 200 may comprise transparent elements, for example made of glass, such as lenses or filters, located opposite the optical transmission/reception regions 357, 358 of chip 350.

The optical filter may be configured to be selectively transparent for a given wavelength range, typically the range comprising the wavelength of the signal transmitted by the light-emitting portion 357, for example infrareds.

Inner cap 200 is made of a polymer material, for example, made of a thermosetting resin. It is, for example, an epoxy resin.

The upper surface of inner cap 200 is mechanically assembled to outer cap 100, for example by a layer 500 of glue or of adhesive, arranged between the two caps 100, 200.

Outer cap 100 comprises a main surface 101 (also called front surface or upper surface) and four lateral surfaces (a first lateral surface 102, a second lateral surface 103, a third lateral surface 104, and a fourth lateral surface 105).

Outer cap 100 comprises a chamber defining a free space to accommodate inner cap 200.

Outer cap 100 may comprise transparent elements, for example made of glass, such as lenses or filters, located opposite the optical transmission/reception regions 357, 358 of chip 350. The transparent elements of inner cap 100 are stacked on the transparent elements of outer cap 200.

The optical filter may be configured to be selectively transparent for a given wavelength range, typically the range comprising the wavelength of the signal transmitted by light-emitting portion 357, for example infrareds.

Outer cap 100 is a metal cap. It is, for example, made of stainless steel or of copper. The stainless steel may be made of SUS 430 or of SUS 316L. Outer cap 100, in either stainless steel or copper, may be nickel-plated (that is, coated with nickel).

In an implementation, the soldering zones 110 are zones located in the lateral surfaces of the cap 100.

A first lateral surface 102 has, at its base (also referred to as a foot), soldering zones 110. Each soldering zone is delimited by a plurality of openings 120. There are at least two openings, for example three openings in a preferred implementation.

By opening, there is meant a through opening. In other words, the opening extends through the entire thickness of the first lateral surface 102.

The openings preferably have an elongated shape, that is, a length/width ratio greater than 2 and preferably greater than 4.

As shown in FIGS. 4A and 4B, openings 120 may have different shapes. They may, for example, be rectangular (FIG. 4A) or elliptical (FIG. 4B).

Openings 120 may have identical or different shapes. Preferably, they are identical.

Preferably, each soldering zone 110 is delimited by three openings 120: two lateral openings and a top opening. A lateral opening may be shared in common by two soldering zones 110 and has a length perpendicular to the base of the first surface 102. The two lateral openings of a soldering zone 110 are parallel to each other. The top opening has a length that is perpendicular to the length of the lateral openings and parallel to the base of the first surface 102.

Outer cap 100 has at least one soldering zone 110, preferably at least two soldering zones 110. It has, for example, four soldering zones.

Soldering zones 110 are preferably formed on a single lateral surface of cap 100. They could be positioned on two opposite lateral surfaces, particularly on the first surface 102 and on the third surface 104.

The surface area of soldering zones 110 is preferably identical to the surface area of the metal pads 310 on support substrate 300.

Once assembled, at least 80%, preferably at least 90% and even more preferably at least 95% of the surface area of the first surface 301 of substrate 300 is covered by outer cap 100.

The first lateral surface 102 has a first height. The second 103, third 104, and fourth 105 lateral surfaces respectively have second, third, and fourth heights. The first height is lower than at least one of the second, third, and fourth heights. Preferably, it is lower than the second, third, and fourth heights. Thus, during the positioning of cap 100 on substrate 300, the second 103, third 104, and fourth 105 lateral surfaces cover the flanks 303 of support substrate 300. The obtained electromagnetic shielding thus has a particularly high performance.

Preferably, lateral surfaces 103, 104, 105 cover at least 50%, even more preferably at least 80%, and even more preferably the entire height of the flanks 303 of substrate 300.

Such an electromagnetic shielding cap may be manufactured by a method comprising a punching step during which openings 120 are formed by perforation of cap 100.

Support substrate 300 and outer cap 100 are mechanically assembled by solder joints 400.

More particularly, the assembly phase comprises: placing of cap 100 into contact with support substrate 300, and more particularly with the first surface 301 of support substrate 300, which is used as a bearing surface, and bonding of cap 100 to support substrate 300.

The bonding is performed by means of a soldering step. Preferably, the soldering is a jet soldering, in which a solder ball jetting is performed. To bond cap 100 to substrate 300, balls made of a solder material (in the molten state) are sprayed onto the surfaces to be assembled (here at the contact area between the metal pads 310 of support substrate 300 and soldering zones 110) and, during the cooling of the solder material, solder joints 400 are formed.

After soldering, each solder joint 400 is in contact, on the one hand, with the soldering zone 110 and cap 100 and, on the other hand, with the metal pads 310 of the substrate 300.

During the soldering, the soldering zones 110 of outer cap 100 are wetted by the balls. Lateral openings 310 enable to laterally limit the propagation of the solder material (and to avoid short-circuits between solder joints). Top opening 310 limits the propagation of solder material 400 towards the top of cap 300. The obtained solder joints 400 have a good ratio of the surface area of soldering zone 110 covered with solder joint 400 to the volume of solder joint 400. The obtained solder joints 400 have a good ratio of the surface area of the pad 310 of support substrate 300 covered with solder joint 400 to the volume of solder joint 400. The mechanical strength of solder joints 400 over time is improved.

On the side of support substrate 300, the extension of solder joint 400 is defined by pads 310.

The ball diameter is, for example, 250 μm for metal pads having a surface area of 250 μm×180 μm or of 250 μm×250 μm.

The balls are made of a solder material (or solderable material), preferably selected from among tin and a tin alloy, such as for example SnAg, SnAgCu (noted SAC).

With such a method, there is no need to implement an additional thermal annealing step.

Such a method is simple and inexpensive to implement.

The obtained electronic circuit has good mechanical strength and an efficient electromagnetic shielding.

The electronic circuit is, in particular, an optical transmission and/or reception electronic circuit and, in particular, a TOF time-of-flight measurement device. Light-emitting portion 357 is configured to transmit a light signal. The signal comes out of inner cap 200 and of outer cap 100. A photosensitive reference surface of light-receiving portion 358 immediately detects the outgoing signal transmitted by light-emitting portion 357, so as to define a signal transmission time. The outgoing signal is intended to be reflected or scattered on an element outside outer cap 100. The reflected or scattered signal is directed towards photosensitive detection portion 358. Light-receiving portion 358 thus detects a time of reception of the reflected signal, and the time elapsed between the transmission time and the reception time is directly proportional to the distance separating the TOF device from the external object.

Such an electronic circuit has applications, in particular in the field of mobile telephony. It also has applications in other industrial fields.

The device is, for example, intended for the automotive industry.

The device may, for example, be used in the industrial field.

The device may also be used in the field of the Internet of things and of smart homes.

It may be used in near-field communications (or NFC).

The device may also be used in the implementation of 5G networks, of data centers, and of servers.

The device is, for example, intended to be used in personal electronics, in 5G connection devices, or more generally in connected devices.

The device is, for example, intended to be used in communications equipment, or in computers and peripherals.

Various embodiments and variants have been described. The person skilled in the art will understand that certain features of these various embodiments and variants could be combined, and other variants will become apparent to the person skilled in the art.

Finally, the practical implementation of the described embodiments and variants is within the abilities of those skilled in the art, based on the indications given above.

1. An electromagnetic shielding cap for an electronic circuit, comprising:
a main surface and four lateral surfaces;
wherein a first lateral surface of said four lateral surfaces has, at a base thereof, at least one soldering zone; and
wherein each soldering zone is delimited by a plurality of openings in the first lateral surface.

2. The cap according to claim 1, wherein each soldering zone is delimited by three openings comprising a top opening above the soldering zone and two lateral openings on opposite sides of the soldering zone, wherein the two lateral openings have lengths extending perpendicular to a length of the top opening and perpendicular to a base of the first lateral surface, and wherein the length of the top opening extends parallel to the base of the first lateral surface.

3. The cap according to claim 1, wherein the first lateral surface has a height smaller than a height of other lateral surfaces of said four lateral surfaces.

4. The cover according to claim 1, wherein the cap is made of metal.

5. The cover according to claim 4, wherein metal for the cap is stainless steel.

6. The cover according to claim 4, wherein metal for the cap is copper.

7. A method of manufacturing the electromagnetic shielding cap of claim 1, wherein the method comprises forming the openings in the cap by punching.

8. An electronic circuit, comprising:
a substrate;
a chip bonded to a first main surface of the substrate; and
an electromagnetic shielding cap comprising:
a main surface and four lateral surfaces;
wherein a first lateral surface of said four lateral surfaces has, at a base thereof, at least one soldering zone; and
wherein each soldering zone is delimited by a plurality of openings;
wherein the first main surface of the substrate is locally covered by metal pads;
wherein the cap and the substrate are assembled to each other by solder joints; and
wherein each solder joint is soldered both to one of the metal pads of the substrate and to one of the soldering zones of the cap.

9. The electronic circuit according to claim 8, wherein the electronic circuit is an optical transmission and/or reception circuit

10. The electronic circuit according to claim 8, wherein at least one other lateral surface of said four lateral surfaces of the cap covers one flanks of the substrate.

11. The electronic circuit according to claim 8, wherein three other lateral surfaces of said four lateral surfaces of the cap cover three corresponding flanks of the substrate.

12. The electronic circuit according to claim 8, further comprising an additional cap, made of polymer material, positioned on the first surface of the substrate, wherein said additional cap is covered by the electromagnetic shielding cap, the additional cap defining a cavity in which the chip is positioned, and wherein the electromagnetic shielding cap is configured to be bonded to the additional cap by a glue layer.

13. The electronic circuit according to claim 8, wherein a surface area ratio between a soldering zone and a metal pad, soldered to each other, is approximately 1.

14. The electronic circuit according to claim 8, wherein the cap covers at least 80% of a surface area of the first main surface of the substrate.

15. The electronic circuit according to claim 8, wherein each soldering zone is delimited by three openings comprising a top opening above the soldering zone and two lateral openings on opposite sides of the soldering zone, wherein the two lateral openings have lengths extending perpendicular to a length of the top opening and perpendicular to a base of the first lateral surface, and wherein the length of the top opening extends parallel to the base of the first lateral surface

16. A method of manufacturing the electronic circuit according to claim 8, comprising:
arranging the chip on the first main surface of the substrate;
wherein a periphery of the first main surface of the substrate is locally covered by metal pads;
positioning the electromagnetic shielding cap on the first main surface of the substrate, the cap being positioned so that the soldering zones are arranged at the metal pads of the substrate; and
performing a soldering operation which forms solder joints, each solder joint being soldered both to one of the metal pads of the substrate and to one of the soldering zones of the cap.

17. The method according to claim 16, wherein performing soldering comprises solder ball jetting.
